(19) United States
(12) Patent Application Publication
(10) Pub. No.: US 2020/0350889 A1
(43) Pub. Date: Nov. 5, 2020

(54) METHOD AND STRUCTURE TO REDUCE IMPACT OF EXTERNAL STRESS AND AGING OF A BAW RESONATOR

(71) Applicant: TEXAS INSTRUMENTS INCORPORATED, Dallas, TX (US)

(72) Inventors: Peter Smeys, San Jose, CA (US); Ting-Ta Yen, San Jose, CA (US)

(21) Appl. No.: 16/752,956

(22) Filed: Jan. 27, 2020

Related U.S. Application Data
(60) Provisional application No. 62/840,833, filed on Apr. 30, 2019.

(51) Int. Cl. H03H 9/17; B81C 1/00; H03H 3/02

(52) U.S. Cl. CPC H03H 9/172; B81C 1/00531; H03H 2003/0421; H03H 2003/028; H03H 3/02

(57) ABSTRACT

A method for manufacturing a Bulk Acoustic Wave (BAW) resonator module is provided. The method includes providing a substrate, defining a platform region on the surface of the substrate, disposing a BAW resonator device on the surface of the substrate within the platform region, and etching an isolation trench circumscribing at least 50% of a circumference of the platform region.

### RELATED APPLICATIONS

This application hereby claims the benefit of and priority to U.S. Provisional Patent Application No. 62/840,833, titled “METHOD AND STRUCTURE TO REDUCE IMPACT OF EXTERNAL STRESS AND AGING OF A BAW RESONATOR”, filed on Apr. 30, 2019 and which is hereby incorporated by reference in its entirety.

### TECHNICAL BACKGROUND

Bulk Acoustic Wave (BAW) resonators are electromechanical devices in which standing acoustic waves are generated by an electrical signal in the bulk of a piezoelectric material. Quartz (SiO₂), aluminum nitride (AlN), and zinc oxide (ZnO) are commonly used as piezoelectric materials in BAW resonators. Simple BAW resonators comprise a thin slice of the piezoelectric material between two metal electrodes which are used to produce the electrical signal in the bulk of the piezoelectric material.

A desired frequency may be obtained by selecting a piezoelectric material based on its natural frequency and specifying the thickness of the piezoelectric material to obtain the desired frequency. More complex BAW resonators may use more complex designs.

BAW resonators are commonly used in communication equipment within high-Q, narrow band-pass filters that are useful particularly in wireless devices operating in crowded frequency ranges. BAW resonators are also used as frequency references in timing devices such as oscillators with a stable output frequency. Whereas, Surface Acoustic Wave (SAW) resonators are useful up to approximately 1.5 GHz, BAW resonators are more efficient at the higher frequencies of 2 GHz to approximately 10 GHz. In addition to radio frequency (RF) filters and duplexers in wireless communication devices, and oscillators for timing applications, BAW resonators are also used within a wide variety of sensors.

### OVERVIEW

In an implementation, a method for manufacturing a Bulk Acoustic Wave (BAW) resonator module is provided. The method includes providing a substrate, defining a platform region on a surface of the substrate, disposing a BAW resonator device on the surface of the substrate within the platform region, and etching an isolation trench into the substrate circumscribing at least 50% of a circumference of the platform region.

In another implementation, a Bulk Acoustic Wave (BAW) resonator module is provided. The BAW resonator module includes a BAW resonator device, and a substrate.

The substrate includes a platform region defined on a surface of the substrate, wherein the BAW resonator device is disposed on the surface of the substrate within the platform region, and an isolation trench circumscribing at least 50% of a circumference of the platform region.

### BRIEF DESCRIPTION OF THE DRAWINGS

While several implementations are described in connection with these drawings, the disclosure is not limited to the implementations disclosed herein. On the contrary, the intent is to cover all alternatives, modifications, and equivalents.

FIGS. 1A-1C illustrate a BAW resonator module in an example implementation.

FIGS. 2A-2C illustrate a BAW resonator module including an isolation trench in an example implementation.

FIG. 3 illustrates a cross-section of a BAW resonator module including an isolation trench in an example implementation.

FIG. 4A illustrates a top view of a BAW resonator module including an isolation trench circumscribing over 50% of the circumference of a platform region.

FIG. 4B illustrates a top view of a BAW resonator module including an isolation trench comprising a pair of bracket-shaped trenches.

FIG. 4C illustrates a top view of a BAW resonator module including an isolation trench circumscribing 100% of the circumference of a platform region.

FIG. 4D illustrates a top view of a BAW resonator module including a pair of isolation trenches circumscribing over 50% of the circumference of a platform region.

FIG. 4E illustrates a top view of a BAW resonator module including a pair of isolation trenches in a gimble configuration.

FIG. 5 illustrates a flow chart of a method of manufacturing a BAW resonator module in an example implementation.

### DETAILED DESCRIPTION

Currently there are two common configurations for BAW resonators. Thin Film Bulk Acoustic Wave Resonators (TFBARs or FBARs) are manufactured using thin film technologies are either edge supported or composite. Solidly Mounted Resonators (SMRs) are disposed on a solid substrate such as a silicon wafer. In some embodiments SMRs include additional reflective layers (called Bragg reflectors) between the BAW resonator device and the substrate in order to minimize leakage of the acoustic wave into the substrate. In some designs, Bragg reflectors are introduced on top of the BAW resonator to also minimize leakage of the acoustic wave into the package materials, such as mold compound.

In designing BAW resonator modules, a number of material considerations must be considered. Since the resonant frequency of BAW resonator devices is determined by the dimensions of very thin piezoelectric materials, it is critical that those materials maintain their dimensions over long term use in a wide variety of conditions.

If stress is applied to the BAW resonator module, the BAW resonator device is also subject to that stress and the piezoelectric material may slightly expand or compress as a result of the applied stress. When the piezoelectrical material expands or compresses, the resonate frequency of the material shifts. In the case of devices operating in very crowded frequency ranges, this frequency shift may result in communication losses such as dropped packets.

Stress applied to the BAW resonator module is produced from a variety of sources, such as physical handling of the device, thermal expansion and contraction of the BAW resonator module, aging of the BAW resonator module, or any of a wide variety of other sources. In order to isolate a BAW resonator device from stresses applied to a BAW resonator module, an isolation trench is etched into the substrate of the module circumscribing at least a portion of a circumference around the device.

Various example embodiments and configurations of isolation trenches within BAW resonator modules configured to reduce stress upon BAW resonator devices within those modules are described herein. These example embodiments and configurations are not meant to be complete bounds of the present invention, but rather examples of embodiments that illustrate the present invention, which is defined by the claims listed below.

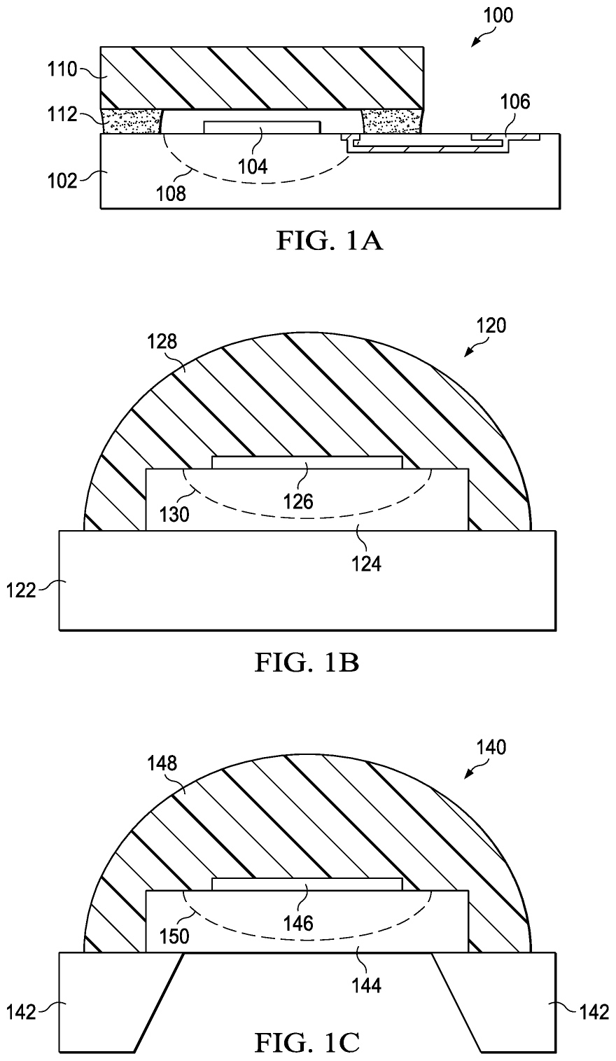

FIG. 1A illustrates a BAW resonator module 100 in an example implementation. In this embodiment, BAW resonator module 100 includes a silicon substrate using an Application Specific Integrated Circuit (ASIC) wafer/BAW wafer 102, along with a BAW resonator device 104 disposed on substrate 102. Note that within substrate 102, underneath BAW resonator device 104 there is an area 108 of substrate 102 which is sensitive to stress. Stresses within these stress-sensitive areas 108 affect BAW resonator device 104 and (as discussed above) may cause the resonate frequency of BAW resonator device 104 to shift.

This example embodiment also includes electrical connections 106 to BAW resonator device 104 within substrate 102. In addition, BAW resonator module 100 includes cap wafer 110 covering BAW resonator device 104 disposed on substrate 102 with adhesive 112. Cap wafer 110 acts as a wafer-level encapsulation and functions to isolate vertical stress from BAW resonator module 100. However, they are not effective against lateral stress on BAW resonator module 100.

Electrical connections 106, cap wafer 110, and adhesives 112 comprise various compositions and configurations in various implementations, all within the scope of the present invention.

FIG. 1B illustrates a BAW resonator module 120 in an example implementation. In this embodiment, BAW resonator module 120 includes substrate 122, along with BAW resonator device 126 disposed on BAW substrate 124. Note that within BAW substrate 124, underneath BAW resonator device 126 there is an area 130 of BAW substrate 124 which is sensitive to stress. Stresses within these stress-sensitive areas 130 affect BAW resonator device 126 and (as discussed above) may cause the resonate frequency of BAW resonator device 126 to shift.

BAW resonator module 120 includes encapsulant 128 covering BAW resonator device 126 and BAW substrate 124. Encapsulant 128 acts as a wafer-level encapsulation with respect to substrate 122.

Encapsulant 128 is preferably an inexpensive plastic molding compound deposited over a spin-on glass passivation layer. The molding compound may be of the type used for encapsulating integrated circuit dies and which is brought into a fluid state, deposited from a reservoir onto BAW resonator device 126 and BAW substrate 124, then cured in place. It may, for example, be an epoxy novolac-based resin or other epoxy, polyimide or silicone resin deposited using a reactive polymer processing technique. Reactive polymer processing is the combined polymerization and processing of reactive polymers or prepolymers in a single operation, and encompasses numerous processing methods such as transfer molding (viz. compressing a heated preform in a mold cavity), conformal spread coating (viz. spinning, spraying, vapor deposition), radial-spread (or “glob top”) coating (viz. dispensing glob of material from a hollow needle), and reaction-injection molding (combining two-part reactive polymers into a mold cavity).

FIG. 1C illustrates a BAW resonator module 140 in an example implementation. In this embodiment, BAW resonator module 140 includes substrate 142, along with BAW resonator device 146 disposed on BAW substrate 144. In this example embodiment, BAW substrate 144 is disposed atop substrate 142, with its edges peripherally supported above an opening formed in substrate 142. The substrate opening over which the BAW resonator device 146 and BAW substrate 144 are disposed may, for example be formed by etching substrate 142 from the back to give the opening illustrated here.

Note that within BAW substrate 144, underneath BAW resonator device 146 there is an area 150 of BAW substrate 144 which is sensitive to stress. Stresses within these stress-sensitive areas 150 affect BAW resonator device 146 and (as discussed above) may cause the resonate frequency of BAW resonator device 146 to shift.

BAW resonator module 140 includes encapsulant 148 covering BAW resonator device 146 and BAW substrate 144. Encapsulant 148 acts as a wafer-level encapsulation with respect to substrate 142.

As described above with respect to FIG. 1B, encapsulant 148 is preferably an inexpensive plastic molding compound deposited over a spin-on glass passivation layer.

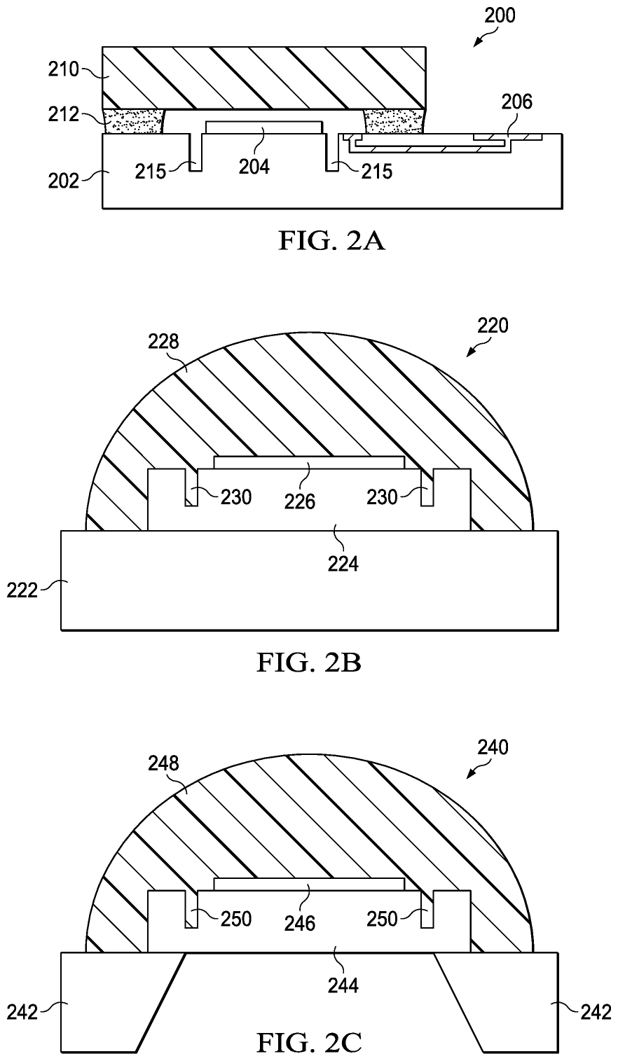

FIG. 2A illustrates a BAW resonator module 200 including an isolation trench 215 in an example implementation. In this embodiment, BAW resonator module 200 includes a silicon substrate using an Application Specific Integrated Circuit (ASIC) wafer/BAW wafer 202, along with BAW resonator device 204 disposed on substrate 202. Note that within substrate 202, underneath BAW resonator device 204 there is an area (not shown) of substrate 202 which is sensitive to stress. As above with respect to FIG. 1A, stresses within these stress-sensitive areas affect BAW resonator device 204 and (as discussed above) may cause the resonate frequency of BAW resonator device 204 to shift.

However, this example implementation includes isolation trench 215 within substrate 202 outside of a circumference of BAW resonator device 204. In an example implementation, isolation trench 215 is etched into substrate 202 using a deep reactive-ion etching (DRIE) process (described in more detail below). Isolation trench 215 is configured based at least in part on expected stresses on BAW resonator device 204 due to stresses on BAW resonator module 200.

Various implementation of isolation trench 215 include a wide variety of configurations of the isolation trench 215 with respect to substrate 202 and BAW resonator device 204, all within the scope of the present invention. For example, isolation trench 212 may be etched into substrate 202 using any of a variety of methods, to a range of depths.

Isolation trench 215 is designed to be deep enough to reduce stress seen by BAW resonator device 204, without being deep enough to compromise the physical structure of substrate 202. In an example implementation isolation trench 215 is etched to a depth of approximately 50% of a thickness of substrate 202. Other implementations use other depths, often between 35% and 75% of a thickness of substrate 202.

This example embodiment also includes electrical connection 202 to BAW resonator device 204 within substrate 202. In addition, BAW resonator module 200 includes cap wafer 210 covering BAW resonator device 204 disposed on substrate 202 with adhesive 212. Electrical connection 206, cap wafer 210, and adhesive 212 comprise various compositions and configurations in various implementations, all within the scope of the present invention.

FIG. 2B illustrates a BAW resonator module 220 in an example implementation. In this embodiment, BAW resonator module 220 includes substrate 222, along with BAW resonator device 226 disposed on BAW substrate 224. Note that within BAW substrate 224, underneath BAW resonator device 226 there is an area (not shown) of BAW substrate 224 which is sensitive to stress. As above with respect to FIG. 1B, stresses within these stress-sensitive areas affect BAW resonator device 226 and (as discussed above) may cause the resonate frequency of BAW resonator device 226 to shift.

However, this example implementation includes isolation trench 230 within BAW substrate 224 outside of a circumference of BAW resonator device 226. In an example implementation, isolation trench 230 is etched into BAW substrate 224 using a deep reactive-ion etching (DRIE) process (described in more detail below). Isolation trench 230 is configured based at least in part on expected stresses on BAW resonator device 226 due to stresses on BAW resonator module 220.

Various implementation of isolation trench 230 include a wide variety of configurations of the isolation trench 230 with respect to BAW substrate 224 and BAW resonator device 226, all within the scope of the present invention. For example, isolation trench 230 may be etched into BAW substrate 224 using any of a variety of methods, to a range of depths.

Isolation trench 230 is designed to be deep enough to reduce stress seen by BAW resonator device 226, without being deep enough to compromise the physical structure of BAW substrate 224. In an example implementation isolation trench 230 is etched to a depth of approximately 50% of a thickness of BAW substrate 224. Other implementations use other depths, often between 35% and 75% of a thickness of BAW substrate 224.

BAW resonator module 220 includes encapsulant 228 covering BAW resonator device 226 and BAW substrate 224. Encapsulant 228 acts as a wafer-level encapsulation with respect to substrate 222.

As described above with respect to FIG. 1B, encapsulant 228 is preferably an inexpensive plastic molding compound deposited over a spin-on glass passivation layer.

FIG. 2C illustrates a BAW resonator module 240 in an example implementation. In this embodiment, BAW resonator module 240 includes substrate 242, along with BAW resonator device 246 disposed on BAW substrate 244. In this example embodiment, BAW substrate 244 is disposed atop substrate 242, with its edges peripherally supported above an opening formed in substrate 242. The substrate opening over which the BAW resonator device 246 and BAW substrate 244 are disposed may, for example be formed by etching substrate 242 from the back to give the opening illustrated here.

Note that within BAW substrate 244, underneath BAW resonator device 246 there is an area (not shown) of BAW substrate 244 which is sensitive to stress. Stresses within these stress-sensitive areas affect BAW resonator device 246 and (as discussed above) may cause the resonate frequency of BAW resonator device 246 to shift.

However, this example implementation includes isolation trench 250 within BAW substrate 244 outside of a circumference of BAW resonator device 246. In an example implementation, isolation trench 250 is etched into BAW substrate 244 using a deep reactive-ion etching (DRIE) process (described in more detail below). Isolation trench 250 is configured based at least in part on expected stresses on BAW resonator device 246 due to stresses on BAW resonator module 240.

Various implementation of isolation trench 250 include a wide variety of configurations of the isolation trench 250 with respect to BAW substrate 244 and BAW resonator device 246, all within the scope of the present invention. For example, isolation trench 250 may be etched into BAW substrate 244 using any of a variety of methods, to a range of depths.

Isolation trench 250 is designed to be deep enough to reduce stress seen by BAW resonator device 246, without being deep enough to compromise the physical structure of BAW substrate 244. In an example implementation isolation trench 250 is etched to a depth of approximately 50% of a thickness of BAW substrate 244. Other implementations use other depths, often between 35% and 75% of a thickness of BAW substrate 244.

BAW resonator module 240 includes encapsulant 248 covering BAW resonator device 246 and BAW substrate 244. Encapsulant 248 acts as a wafer-level encapsulation with respect to substrate 242.

As described above with respect to FIG. 1B, encapsulant 248 is preferably an inexpensive plastic molding compound deposited over a spin-on glass passivation layer.

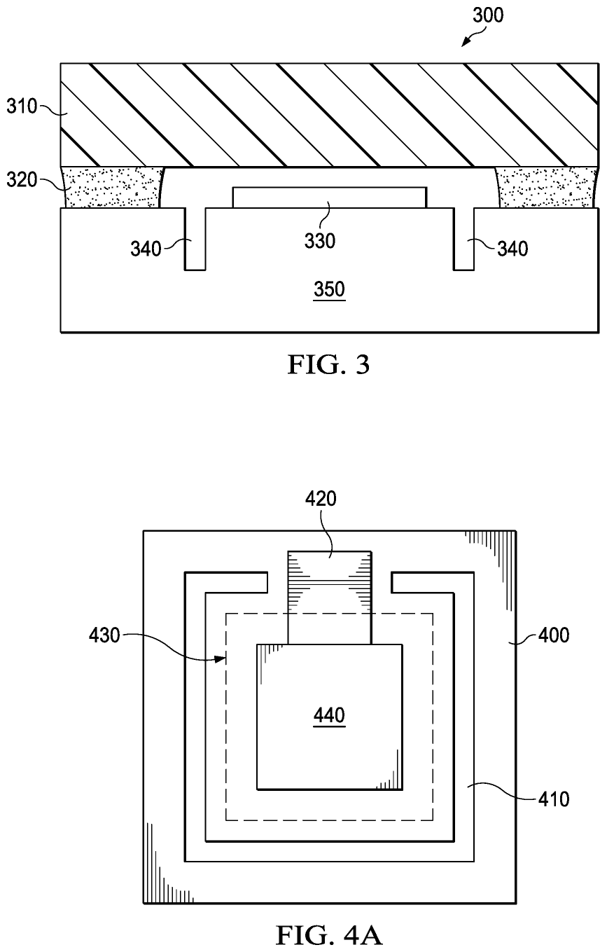

FIG. 3 illustrates a cross-section of a BAW resonator module 300 including an isolation trench 340 in an example implementation. In this example implementation, BAW resonator module 300 includes cap wafer 310 adhered to substrate 350 with adhesive 320 covering BAW resonator device 330. Isolation trench 340 is shown on both sides of BAW resonator device 330 in a configuration designed to reduce stress on BAW resonator device 330.

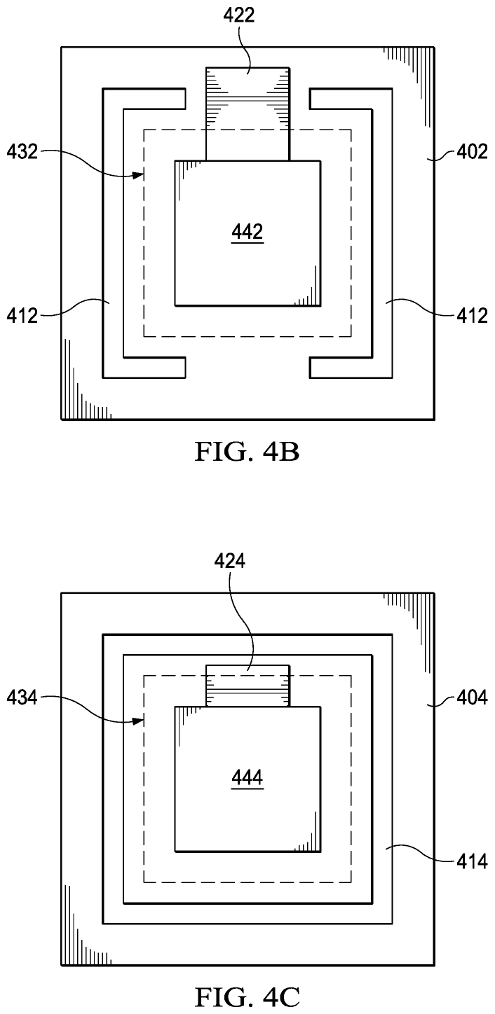

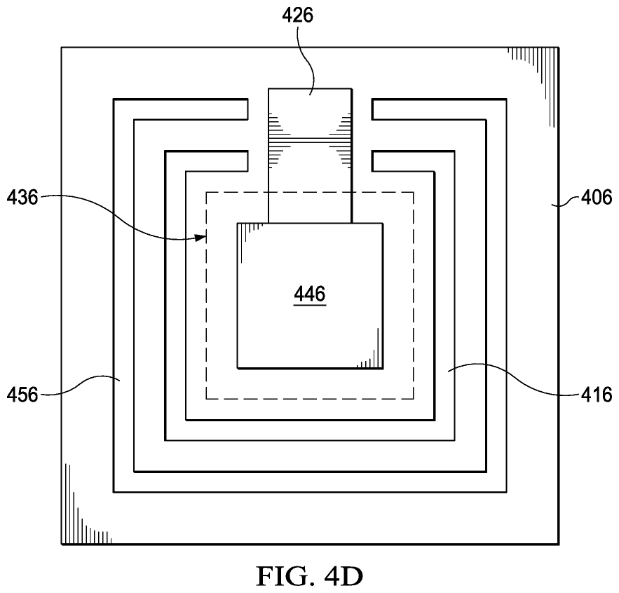

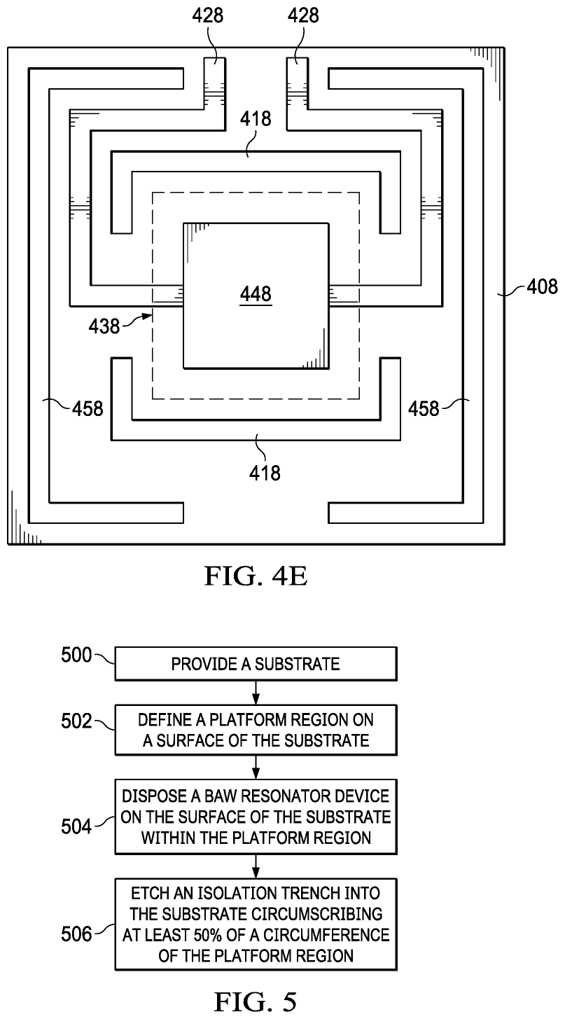

Various implementations of the present invention utilize a wide variety of configurations of isolation trench 340 with respect to BAW resonator device 330. In fact, some implementations of isolation trench 340 may comprise two or more trenches at various configurations and locations around the circumference of BAW resonator device 330. A variety of example implementations of isolation trench 330 are illustrated in FIGS. 4A-4E and described below.

FIG. 4A illustrates a top view of a BAW resonator module including an isolation trench 410 circumscribing over 50% of the circumference of a platform region 430. In this example implementation, a BAW resonator module including BAW resonator device 440 and substrate 400 is illustrated.

Here, platform region 430 has been defined on a surface of substrate 400 as a region and location where BAW resonator device 440 is disposed on substrate 400. In this implementation, platform region 430 is not physically etched or otherwise constructed within or on substrate 400. It is simply defined as a region on a surface of substrate 400 where BAW resonator device 440 is disposed.

In this example implementation, isolation trench 410 has been etched into substrate 400 in a configuration surrounding platform region 430 (and BAW resonator device 440) on over three sides in a U-shaped configuration. Also, in this example implementation, electrical connections 420 are shown disposed on substrate 400.

FIG. 4B illustrates a top view of a BAW resonator module including an isolation trench 412 comprising a pair of bracket-shaped trenches 412. In this example implementation, a BAW resonator module including BAW resonator device 442 and substrate 402 is illustrated.

Here, platform region 432 has been defined on a surface of substrate 402 as a region and location where BAW resonator device 442 is disposed on substrate 402. In this implementation, platform region 432 is not physically etched or otherwise constructed within or on substrate 402. It is simply defined as a region on a surface of substrate 402 where BAW resonator device 442 is disposed.

In this example implementation, an isolation trench 412 has been etched into substrate 402 in a configuration surrounding platform region 432 (and BAW resonator device 442) on over two sides as a pair of bracket-shaped trenches 412. Although the pair of bracket-shaped trenches 412 are not connected, they serve to isolate BAW resonator device 442 from lateral stress.

This configuration is useful in implementations where expected stresses will occur in a known stress vector. In this example, the orientation of the isolation trench 412 is determined at least in part based on the direction/vector of expected stresses on BAW resonator device 442.

Also, in this example implementation, electrical connections 422 are shown disposed on substrate 402.

In other similar configurations, isolation trench 412 may have curved corners resulting in C-shaped trenches.

FIG. 4C illustrates a top view of a BAW resonator module including an isolation trench circumscribing 100% of the circumference of a platform region. In this example implementation, a BAW resonator module including BAW resonator device 444 and substrate 404 is illustrated.

Here, platform region 434 has been defined on a surface of substrate 404 as a region and location where BAW resonator device 444 is disposed on substrate 404. In this implementation, platform region 434 is not physically etched or otherwise constructed within or on substrate 404. It is simply defined as a region on a surface of substrate 400 where BAW resonator device 444 is disposed.

In this example implementation, isolation trench 414 has been etched into substrate 404 in a configuration surrounding platform region 434 (and BAW resonator device 444) on all four sides. Also, in this example implementation, electrical connections 424 are shown disposed on substrate 404.

FIG. 4D illustrates a top view of a BAW resonator module including a pair of U-shaped isolation trenches 416 and 456, each circumscribing over 50% of the circumference of platform region 436. In this example implementation, a BAW resonator module including BAW resonator device 446 and substrate 406 is illustrated.

Here, platform region 436 has been defined on a surface of substrate 406 as a region and location where BAW resonator device 446 is disposed on substrate 406. In this implementation, platform region 436 is not physically etched or otherwise constructed within or on substrate 406. It is simply defined as a region on a surface of substrate 406 where BAW resonator device 446 is disposed.

In this example implementation, a pair of isolation trenches 416 and 456 have been etched into substrate 406 in a configuration circumscribing over 50% of the circumference of platform region 436 (and BAW resonator device 446) as a pair of U-shaped trenches 416 and 456. Although the pair of U-shaped trenches 416 and 456 are not connected, they serve to isolate BAW resonator device 446 from lateral stress.

This configuration is useful in implementations where expected stresses will occur in a known stress vector. In this example, an orientation of the isolation trenches 416 and 456 are determined at least in part based on the direction/vector of expected stresses on BAW resonator device 446.

Also, in this example implementation, electrical connections 426 are shown disposed on substrate 406.

FIG. 4E illustrates a top view of a BAW resonator module including isolation trenches 418 and 458, in a gimble configuration. In this example implementation, a BAW resonator module including BAW resonator device 448 and substrate 408 is illustrated.

Here, platform region 438 has been defined on a surface of substrate 408 as a region and location where BAW resonator device 448 is disposed on substrate 408. In this implementation, platform region 438 is not physically etched or otherwise constructed within or on substrate 408. It is simply defined as a region on a surface of substrate 408 where BAW resonator device 448 is disposed.

In this example implementation, two pairs of C-shaped isolation trenches 418 and 458 have been etched into substrate 408 in a gimble configuration. Inner isolation trench 148 comprises two C-shaped trenches disposed above and below BAW resonator device 448. Outer isolation trench 458 comprises two C-shaped trenches disposed to the left and right of BAW resonator device 448. Together, inner and outer isolation trenches 418 and 458 comprise a gimble configuration around BAW resonator device 448.

This configuration is useful in implementations where expected stresses do not occur in a known stress vector. The gimble configuration of isolation trenches 418 and 458 allow the BAW module to resist stress from any vector within substrate 408.

Also, in this example implementation, electrical connections 428 are shown disposed on substrate 408.

Note that FIGS. 4A-4E are not drawn to scale, they are simply illustrations of example configurations of BAW resonator modules including isolation trenches. Many configurations of the elements illustrated in FIGS. 4A-4E are possible within the scope of the present invention.

FIG. 5 illustrates a flow chart of a method of manufacturing a BAW resonator module in an example implementation. In this example method, substrate 400 is provided, (operation 500), then platform region 430 is defined on a surface of substrate 400, (operation 502). Note that platform region 430 is not physically etched or otherwise constructed within or on substrate 400. It is simply defined as a region on a surface of substrate 400 where BAW resonator device 440 is disposed.

BAW resonator device 440 is disposed on substrate 400 within platform region 430, (operation 504). In some example embodiments, BAW resonator device 440 is connected to other devices via electrical connections 420. In other example implementations, electrical connections 420 are constructed within substrate 400.

Isolation trench 410 is etched into substrate 400 using a deep reactive-ion etching (DRIE) process, and circumscribes at least 50% of a circumference of the platform region 430, (operation 506).

While other etching processes may be used within the scope of the present invention, this example embodiment uses the DRIE process. DRIE is used to create deep, steep-sided trenches in silicon substrates with high aspect ratios (trench depth/feature width). These aspect ratios exceed 10:1 in some implementations. The Bosch Process of DRIE repeats a cycle of isotropic etching of the substrate and deposition of a protective film. The silicon substrate is etches using a SF₆ plasma, and a C₄F₈ plasma cycle creates the protective layer.

What is claimed is:

1. A method for manufacturing a Bulk Acoustic Wave (BAW) resonator module, the method comprising:
providing a substrate;
defining a platform region on a surface of the substrate;
disposing a BAW resonator device on the surface of the substrate within the platform region; and
etching an isolation trench into the substrate circumscribing at least 50% of a circumference of the platform region.

2. The method of claim 1 wherein the isolation trench circumscribes at least three sides of the circumference of the platform region.

3. The method of claim 1, wherein an orientation of the isolation trench is determined at least in part based on expected stresses on the BAW resonator device.

4. The method of claim 1, wherein the isolation trench is etched using a deep reactive-ion etching (DRIE) process.

5. The method of claim 1, wherein a depth of the isolation trench is between 35% and 75% of a thickness of the substrate.

6. The method of claim 5, wherein the depth of the isolation trench is approximately 50% of the thickness of the substrate.

7. The method of claim 1, wherein the BAW resonator device is encapsulated with a molding compound.

8. The method of claim 1, further comprising:
etching a second isolation trench into the substrate circumscribing at least 50% of a circumference of the platform region.

9. The method of claim 1, wherein the isolation trench comprises inner and outer isolation trenches in a gimble configuration.

10. The method of claim 1, wherein the isolation trench comprises:
a first bracket-shaped trench circumscribing at least a first side of the platform region; and
a second bracket-shaped trench circumscribing at least a second side of the platform region opposite to the first side of the platform region.

11. A Bulk Acoustic Wave (BAW) resonator module, comprising:
a BAW resonator device; and
a substrate comprising:
a platform region defined on a surface of the substrate, wherein the BAW resonator device is disposed on the surface of the substrate within the platform region; and
an isolation trench circumscribing at least 50% of a circumference of the platform region.

12. The BAW resonator module of claim 11 wherein the isolation trench circumscribes at least three sides of the platform region.

13. The BAW resonator module of claim 11, wherein an orientation of the isolation trench is determined at least in part based on expected stresses on the BAW resonator device.

14. The BAW resonator module of claim 11, wherein the isolation trench is etched using a deep reactive-ion etching (DRIE) process.

15. The BAW resonator module of claim 11, wherein a depth of the isolation trench is between 35% and 75% of a thickness of the substrate.

16. The BAW resonator module of claim 15, wherein the depth of the isolation trench is approximately 50% of the thickness of the substrate.

17. The BAW resonator module of claim 11, wherein the BAW resonator device is encapsulated with a molding compound.

18. The BAW resonator module of claim 11, wherein the substrate further comprises:
a second isolation trench circumscribing at least 50% of a circumference of the platform region.

19. The BAW resonator module of claim 11, wherein the isolation trench comprises inner and outer isolation trenches in a gimble configuration.

20. The BAW resonator module of claim 11, wherein the isolation trench comprises:
a first bracket-shaped trench circumscribing at least a first side of the platform region; and
a second bracket-shaped trench circumscribing at least a second side of the platform region opposite to the first side of the platform region.
